(19) United States
(12) Patent Application Publication
(10) Pub. No.: US 2014/0299902 A1
(43) Pub. Date: Oct. 9, 2014

(54) Articles and methods for rapid manufacturing of solid state light sources

(71) Applicants: Scott M. Zimmerman, Basking Ridge, NJ (US); William R. Livesay, San Diego, CA (US); Richard L. Ross, Del Mar, CA (US); Eduardo DeAnda, San Diego, CA (US); Chad R. Livesay, Encinitas, CA (US); Daniel B. Livesay, San Diego, CA (US)

(72) Inventors: Scott M. Zimmerman, Basking Ridge, NJ (US); William R. Livesay, San Diego, CA (US); Richard L. Ross, Del Mar, CA (US); Eduardo DeAnda, San Diego, CA (US); Chad R. Livesay, Encinitas, CA (US); Daniel B. Livesay, San Diego, CA (US)

(73) Assignee: Goldeneye, Inc., San Diego, CA (US)

(21) Appl. No.: 13/694,925

(22) Filed: Jan. 17, 2013

Related U.S. Application Data
(60) Provisional application No. 61/632,165, filed on Jan. 18, 2012.
(60) Provisional application No. 61/634,485, filed on Feb. 28, 2012.

(51) Int. Cl. H01L 33/00; H01L 33/62; H01L 33/50

(52) U.S. Cl. CPC H01L 33/005; H01L 33/50; H01L 33/62
USPC 257/98; 438/27

(57) ABSTRACT

Rapid manufacturing processes and designs based on solid luminescent elements form solid state light sources. Direct attach, as well as other LED types, are embedded or affixed to the solid luminescent elements to form low cost solid state light sources.

### REFERENCE TO PRIOR APPLICATION

This application claims the benefit of U.S. Provisional Patent Application Ser. No. 61/632,165, which was filed on Jan. 18, 2012, and U.S. Provisional Patent Application Ser. No. 61/634,485, which was filed on Feb. 28, 2012, both of which are herein incorporated by reference.

### BACKGROUND OF THE INVENTION

Historically, lighting has been based on self cooling inorganic designs formed using high temperature processes. This is mainly driven by the temperatures generated, the need for a controlled atmosphere envelope, and the need for environmental stability both to the light generated and the surrounding ambient environment (rain, snow, solar, dust, etc.). While LED solid state lighting sources do not typically require a controlled atmosphere envelope, the other issues remain. The need therefore exists for low cost articles and methods associated with inorganic materials for LED solid state lighting. This is especially true for luminescent materials which tend to degrade both thermally and environmentally with time. The use of powders in silicones or epoxies leads to efficiency losses, color shifting, and other reliability issues due to degradation of the organic matrix under high flux levels and migration of moisture into the materials themselves. The intent of this filing is to disclose methods and articles that can be used to eliminate these deficiencies.

The advent of efficient fiber laser technologies enables localized efficient heating of surfaces and volumes to temperatures sufficient for melt fusing and sintering to occur. This specification discloses the use of fiber laser systems as an efficient means of forming components for solid state lighting. In particular, rapid melt fusing or sintering of wavelength conversion elements, trimming of wavelength conversion elements, and formation of interconnect structures based on laser fused conductive inks are disclosed.

GaN based LEDs are grown at very high temperatures (over 700 degrees C.). A variety of high temperature annealing steps creates the ohmic contacts required to electrically connect to the LEDs themselves. However, once formed, the LEDs are susceptible to high temperature processes especially in the presence of water vapor or hydrogen. Substrate free LEDs (LEDs that are not attached via an eutectic or other means of wafer bonding to a secondary substrate) can withstand short exposures of up to 400 degrees C. In conventional LED fabrication, several mechanisms lead to degradation at temperatures over 150 degrees C., these include degradation of metal contacts, passivation of the p layer, increased edge leakage, and degradation of current spreading layers. Wafer bonded LEDs are typically limited to even lower temperatures based on the wafer bonding technique used. Most inorganic binders and sintering materials required temperatures greater than 400 degrees C. to efficiently react. The need exists for processes which allow for efficient localized rapid heating of inorganic materials such that each LED is not exposed to high temperatures for an extended period of time. Fiber lasers are ideally suited for this application.

### SUMMARY OF THE INVENTION

Fiber lasers can be over 50% efficient from an electrical to optical conversion standpoint. Fiber lasers also allow for very controlled placement of the energy onto a surface or within a volume and ease of integration into production processes. Conventional sintering and melt fusing requires that the entire assembly is heated to the sintering temperature. The ability to very precisely deliver a high energy input rapidly into a specific region of an assembly is critical to prevent unnecessary thermal stressing of LEDs and other temperature sensitive parts. As previously disclosed by the present inventors (for example, in LEDs can be integrated into thermally conductive luminescent elements to make high powered packages and self cooling light sources. Fiber lasers can also deliver a beam quality approaching the diffraction limit which allows for very precise spot sizes. Beam shaping including flat tops are also possible either with a secondary optic or shaped fiber.

Ideally the LEDs would be integrated using inorganic materials because organic materials and their associated CH and CF bonds can be broken by the UV/blue wavelengths emitted by the LEDs themselves. This is a fundamental limitation of all organic based materials. The organic materials also suffer from low thermal conductivity and low thermal stability. Unfortunately, inorganic materials tend to be processed at elevated temperatures which are detrimental to LEDs.

This specification discloses methods and articles based on fiber laser processing that limits the amount and duration of heating that the LEDs are exposed to during bonding, interconnect formation, and packaging. In particular, methods of sintering and fusing inorganic materials such as, but not limited to, silver conductive inks, ceramic powders and glasses, as well as composites made from these materials, can use fiber laser based systems. While other laser systems are anticipated, fiber lasers are preferred based on their higher efficiency, reliability, low cost per watt and output wattage.

Fiber lasers can rapidly sinter or melt fuse transparent/translucent ceramic wavelength conversion elements for use in solid state lighting applications, both as packages and self cooling light sources. Further, fiber lasers can be used as trimming means for adjusting the color temperature of packages and self cooling light sources, based on spatially ablating the transparent/translucent ceramic wavelength conversion element.

Fiber lasers can also be used in laser liftoff applications. In particular, a fiber laser based system creates a narrow line pattern (less than 10 microns wide×greater than 100 micron wide) coupled to a galvo for laser liftoff of nitride foils from nitride templates (typically grown of sapphire). An interconnect means laser fuses conductive inks to contact surfaces on LED and external interconnects, thereby reducing the thermal heating of the LED itself while allowing for the use inorganic binders in the conductive inks.

Solid state light sources can be based on lateral LEDs and direct attach LEDs. Direct attach LEDs attached to solid luminescent elements in particular lend themselves to rapid fabrication techniques including laser soldering and laser trimming for color balancing.

By embedding LED in solid luminescent elements rapid fabrication techniques can be used, which dramatically reduce overall cost. The solid luminescent element enables the incorporation of electrical interconnects which are robust enough for high speed processes like laser soldering. Fiber lasers also can be used to form the solid luminescent element, to cut pockets in the solid luminescent element, and to dice the solid luminescent element. All these processes reduce the cost of manufacturing of the overall light sources.

### BRIEF DESCRIPTION OF THE DRAWINGS

FIG. 1 depicts a side view of a standard prior art LED package.

FIG. 2 depicts a side view of a ceramic wavelength conversion element with a conductive ink interconnect and an embedded LED in accordance with the present invention.

FIG. 3A depicts a side view of a freestanding ceramic wavelength conversion element being sintered or melt fused using collimated fiber laser input in accordance with the present invention. FIG. 3B is a graph showing the transmission windows for the wavelengths of light emitted by a luminescent thermally conductive element of the present invention.

FIG. 4 depicts a side view of processing apparatus for selective fusing of an inorganic binder based conductive ink onto a ceramic wavelength conversion element of the present invention.

FIG. 5 depicts a side view of a fiber laser fused interconnect structure of an LED embedded within a wavelength conversion element in accordance with the present invention.

FIG. 6 depicts a side view of an embedded LED/wavelength conversion element package based on fiber laser fused inorganic conductive inks in accordance with the present invention.

FIG. 7A depicts a side view of a scanning fiber laser liftoff system of the present invention. FIG. 7B is an enlarged view depicting the beam pattern of the laser beam emitted by the laser system of FIG. 7A.

FIG. 8 depicts a side view of a fiber laser system for trimming, cutting pockets, and cutting extraction elements in wavelength conversion elements in accordance with another aspect of the present invention.

FIG. 9A depicts a side view of a scanning fiber laser via cutting system of the present invention. FIG. 9B is a close-up side view depicting the use of a pattern recognition system in identifying elements in FIG. 9A.

FIG. 10A depicts a side view of a scanning fiber laser fusing system for transparent dielectrics of the present invention. FIG. 10B is a close-up side view of a sintered transparent dielectric formed on a thermally conductive luminescent element in the laser fusing system of FIG. 10A.

FIG. 11A depicts a side view of a lambertian LED package with a direct attach LED. FIG. 11B depicts a top view of a solder pattern corresponding to the direct attach LED and solid luminescent element of FIG. 11A.

FIG. 12 depicts a side view of an isotropic LED package with direct attach LED with optional water cooling.

### DETAILED DESCRIPTION OF THE INVENTION

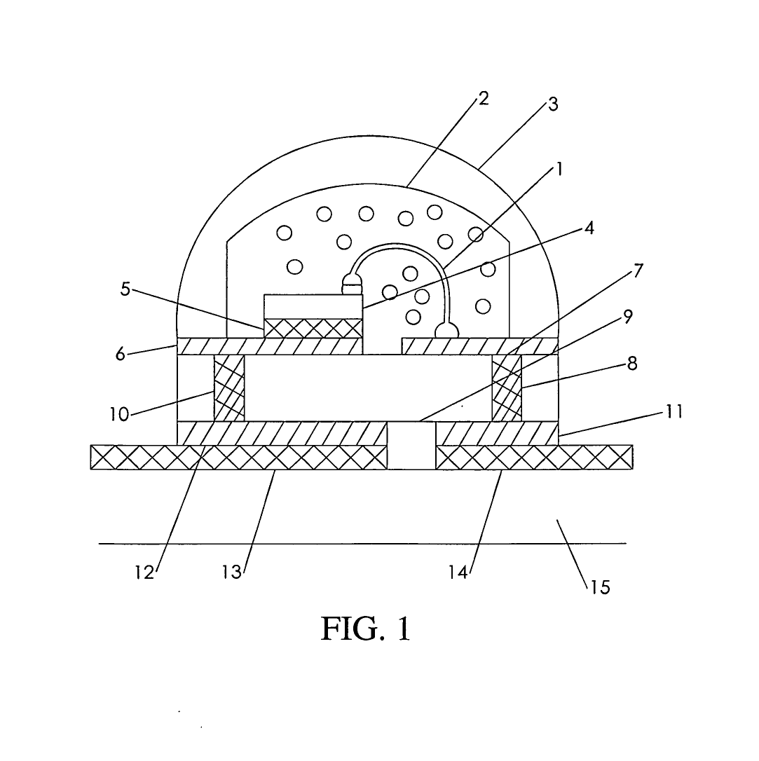

FIG. 1 illustrates a standard prior art light emitting diode (LED) package. A package is defined as containing at least one LED and at least one layer of electrical and thermal interconnect means. As an example, a blue or UV LED 4 is connected by one or more wirebonds 1 to package contact 7. In a vertical LED, the second contact is on the backside of the LED 4 with a eutectic solder layer 5 which attaches to a second package contact 6. Typically a dielectric layer 9 has internal holes (vias) 8 and 10 to the external package contacts 12 and 11. A wavelength conversion layer 2 is typically an epoxy or silicone matrix with phosphor powders dispersed within the organic matrix. This wavelength conversion layer is then bonded to a lens 3 which increases the optical extraction from the system and changes the far field optical distribution by increasing the solid angle of light which can be extracted from the LED 4 and the wavelength conversion layer 2. The external package contacts 12 and 11 are then soldered to external contacts 13 and 14 on substrate 15 which allow for power to be applied to LED 4.

In many cases the substrate 15 is formed of an intrinsically thermally conductive material like AlN or a metal core PCB. In this configuration of a thermally conductive substrate, heat generated within the phosphor powder due to Stokes and other losses must be conducted through the organic matrix of the wavelength conversion layer 2 to the LED 4 down through the package 9 into substrate 15 to reach the ambient atmosphere or cooling means. Each interconnect represents a thermal resistance and thermal interface boundary that determines the temperature of the phosphor powder and LED. Since organic materials have thermal conductivity significantly less than 1 W/m/K, the phosphor powder can reach very high temperatures within the wavelength conversion layer 2. Elevated temperatures within the phosphor powder leads to reduced efficiency with thermal quenching beginning as low as 100 degrees C. for common phosphors like CeYag. In addition, elevated temperatures, moisture, and high flux levels lead to photocatalytic reaction between the phosphor powders and the organic matrix materials. Lens 3 may also be adversely affected for the same reason the plastic greenhouse films degrade under solar incidence of 1000 W/m2. In comparison, the power LED packages can generate more than 1 optical watt per mm2 which is 1000× higher than the peak solar incidence a greenhouse film would be exposed to.

One of the main benefits of solid state lighting is its longer lifetime. The high surface area to volume ratio of the phosphor powder can lead to degradation of both the phosphor powder itself and the surrounding organic matrix due to oxidative and thermal effects. As such, powders in organic matrix materials represent a lifetime issue for conventional LED packaging. It should be noted that phosphor powder even though it may have a microscopic thermal conductivity equal to a solid luminescent element, once placed within a low thermal conductivity matrix like air or silicone, becomes thermal isolated from the surrounding ambient environment by the low thermal conductivity matrix. The heat generated within the phosphor powders by Stokes losses and quantum efficiency losses can easily drive the surface temperature of the individual phosphor particles well above the thermal quenching point of even CeYag (350 degrees C.) in the case of high flux sources such as recycling cavities. Even elevating the surface temperature of the individual phosphor powders to 150 degrees C. decreases the efficiency of most luminescent materials by at least 10 to 15%. This localized heating can be overcome through the use of solid luminescent elements as disclosed by the present inventors. The detrimental effects of using organic materials are even more pronounced when moisture, heat, and long term operation are combined. As stated earlier, the need exists for inorganic solutions to solid state lighting which are environmentally robust and still economical.

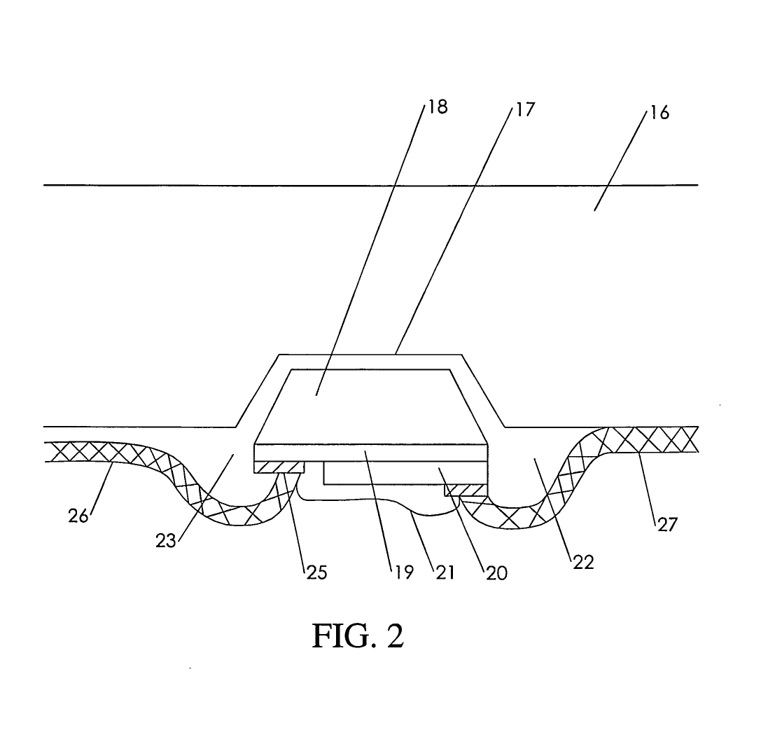

FIG. 2 depicts a lateral LED 18 embedded within a thermally conductive luminescent element 16 of the present invention. In this embodiment the thermally conductive luminescent element 16 provides wavelength conversion but also provides a thermal conduction pathway for heat removal for both itself and lateral LED 18. While heat can still be removed directly from the lateral LED 18 the surface area from which heat can be extracted is larger for the non-electrical contact surfaces than the electrical contact surfaces. By using the thermally conductive luminescent element 16 as a secondary thermal conduction path much higher drive levels can be realized. Lateral LED 18 can have efficiencies over 50% as such the heat generated within the thermally conductive luminescent element 16 can be equal or larger than the heat generated within the lateral LED 18. Using this approach, heat can still be removed directly from the lateral LED 18. In this manner, heat can be extracted through both the thermally conductive luminescent element 16 and the interconnects 27 and 26. Typically the lateral LED 18 is bonded to the thermally conductive luminescent element 16 using a transparent dielectric 17 consisting of, but not limited to, polysiloxane, polysilazane, low temperature glasses, or low temperature oxides, which may or may not contain luminescent materials. Barriers 21, 22, and 23 are also typically transparent dielectric materials which may or may not contain luminescent materials. Vertical and edge contact LED designs are also embodiments of this invention. Thermally conductive luminescent element 16 can consist of composites of luminescent materials and non-luminescent materials such as alumina and rare earth doped garnets including but not limited to YAG, GdAG, LuAG, and YGdAG. Other non-luminescent materials such as ZnO, GaN, MgO, Sialon, AlON, and other non-luminescent materials that exhibit high transmission in the visible region and thermal conductivity greater than 1 W/m/K. Most preferred are materials with thermal conductivity greater than 10 W/m/k such that sufficient thermal spreading is possible. Luminescent materials include but are not limited to inorganic phosphors such as garnets, aluminates, nitrides, oxynitrides. In particular, luminescent materials which have very high processing temperatures are preferred such that incorporation into lower temperature oxides like alumina can be done with little reaction. Even more preferred are composites that contain phosphor powders with particles sizes less than 500 nm to reduce scatter losses. The thermally conductive luminescent element 16 may also consist of non-luminescent materials such as polycrystalline alumina with at least one luminescent element added to transparent dielectric 17 and/or barrier layers 21, 22, and 23.

Substantially inorganic dielectric high temperature adhesives with thermal expansions coefficients between 2 and 13 ppm/degree C. are used for bonding the semiconductor layers in the LED. Alternatively, high temperature organic materials may also be used for transparent dielectric 17. Most preferred is a high refractive index and high thermal conductivity interface material to maximize extraction of light from LED 18 into thermally conductive luminescent element 16. An LED 18 typically has a thermal expansion between 3 and 8 ppm/degree C. with a refractive index between 2.1 for nitride LEDs to 3.1 for AlInGaP LEDs. Nitride LEDs grown on silicon carbide range from 2.1 to 2.5. Nitride LEDs grown on sapphire range from 1.9 to 2.1. Ceramic CeYag and other luminescent composites also have expansion coefficients between 3 and 10 ppm/degree C with a refractive index ranging from 1.7 to 2.0. Anisotropic composites such as composites containing oriented hexagonal boron nitride can also be used as the adhesive. As an example, a composite containing Ce(0.04) Y(1.46)Gd(1.5)Al(5)O(12) at 4 wt % within an oriented hexagonal boron nitride matrix would exhibit a much higher thermal conductivity in one plane and also exhibit an anisotropic optical scatter nature as well. Oxides, nitrides, oxynitrides, tantalates, and other inorganic materials that congruently melt may be used to replace the hexagonal boron nitride matrix disclosed above. Alternately, a luminescent powder such as (Y,Gd)AG with a cerium doping level of 0.03 wt % can be melt fused or sintered by itself. Dopant concentration levels are determined by the desired amount of blue to yellow light conversion desired. While yellow/orange luminescent materials are used here as an example, it is understood that any congruent melting luminescent material may be used and that non-luminescent/luminescent mixtures may be used as well. In the case of non-luminescent/luminescent mixtures, higher dopant concentrations are typically used in the luminescent materials compared to luminescent only materials if a particular thickness is desired. In general, a congruent melting matrix and a congruent luminescent crystalline material including but not limited to garnets, tantalates, silicates, oxynitrides, or zirconates are disclosed. The use of air, nitrogen, or inert atmospheres allows congruent melting without decomposition. As an example BN can be sintered and processed in inert atmospheres but not air. Lateral LED 18 has two contacts, an n side 19 and p side 20 which are contacts 25 and 24 respectively. Ideally interconnects 27 and 26 would be inorganic silver traces which are directly fired onto contacts 25 and 24. This approach for fabricating the LED allows for the use of printable conductors, more commonly utilized in the solar industry. For direct attach LEDs it is critical that the interconnect be flat, solderable, and smooth enough to ensure reliable connection. As an example, a solid luminescent element with a flatness less than 5 microns/inch formed via injection molding, dry pressing, tape casting, or extrusion followed by sintering and/or hot isostatic pressing. Subsequent post processing to form a flat surface such as lapping, grinding, or wire saw processing may also be used to form a flat substrate. On this surface silver ink designed specifically for direct attach applications can be applied. Typically less than 5 micron surface roughness is required because the eutectic solder contacts on commercially available direct attach LEDs have a thickness less than or equal to 5 microns. Another critical parameter is the thermal expansion of the thermal conductive luminescent element 16. Most preferred are materials with a thermal expansion coefficient which closely matches the thermal expansion coefficient of the LED 18. These materials however sinter at temperatures ranging from 400 degrees C. to 1000 degrees C. Lower temperature inks based on organic binders are available but can suffer from similar environmental issues to those experienced by the organic matrix and lens materials discussed in FIG. 1. Additional problems with organic binders are silver migration which occurs due to electrical potential and degradation of reflectivity due to moisture oxidation of the silver. Nano particle silver coated with low temperature inorganic glasses as provided by Cabot is a preferred material due to its high reflectivity and low firing temperature of 420 degrees C. In general, inorganic binder systems are preferred along with rapid heating processes. Even more preferred are rapid heating processes which are localized as provided by laser or directed energy processes such that the minimum heat load is imparted to lateral LED 18. Alternately the lateral LED 18 may be a direct die attach LED which eliminates the need for interconnects 27 and 26.

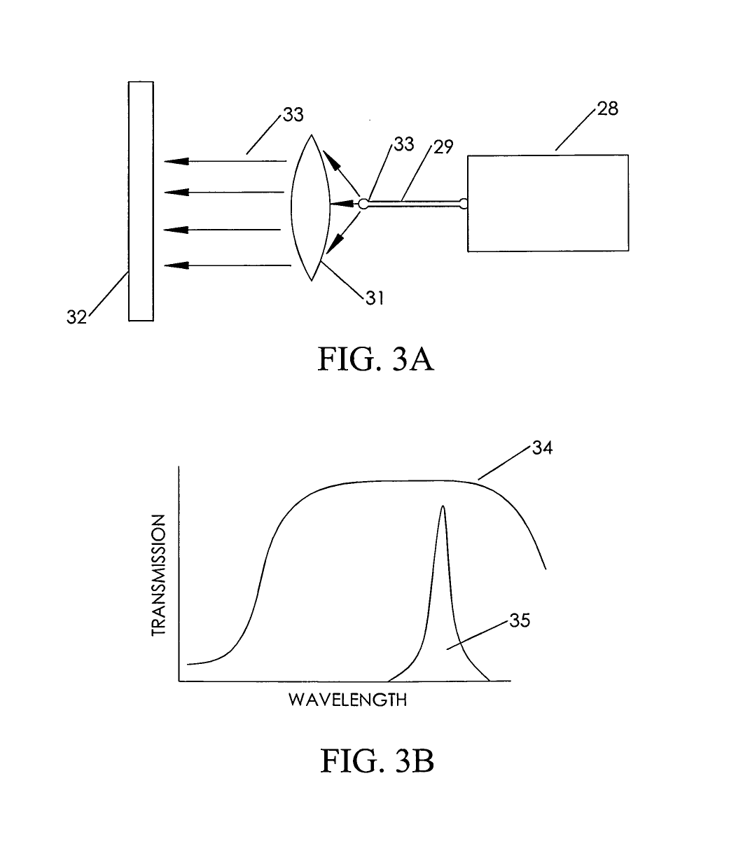

FIG. 3A depicts a laser sintering/melt fusing apparatus for rapid sintering and/or melt fusing of luminescent thermally conductive element 32. It is important to clearly differentiate sintering from melt fusing. In sintering operation discrete particles condense together based on diffusional growth at temperatures below the melting point of at least one of the particles in the mixture. In melt fusing processing temperatures are above the melting point which allows for rapid consolidation and mixing of all the materials being heated. Sintering is typically used to reduce the processing temperature and to create net shape parts. In melt fusing processes secondary forming operations such as slicing, forging, or pressing is used to create net shape parts. In general melt fused processes create near spherical parts due to surface tension consolidation driven by similar forces which cause the formation of spherical raindrops. In this setup, fiber laser 28 outputs coherent light through optical fiber 29. Optical fiber 29 couples coherent light output 30 through an optical system 31 which consists of, but is not limited to a lens, reflector, diffractive optic, GRIN (graded index) lens, or other imaging or non-imaging optical element output 30 into a directed beam 33 onto luminescent thermally conductive element 32. The high efficiency (approaching 50%) and direct nature of directed beam 33 allows for efficient rapid input of the energy into luminescent thermally conductive element 32.

Typically luminescent thermally conductive element 32 has an intrinsic transmission window as depicted in curve 34 of FIG. 3B. Laser emission wavelengths 35 within this intrinsic transmission window are a preferred embodiment of this invention. By matching the laser emission wavelength 35 and transmission window (e.g. absorption length) of luminescent thermally conductive element 32, more uniform heating within the volume of the luminescent thermally conductive element 32 can be realized. Even more preferably the luminescent thermally conductive element 32 has a thickness equal to or less than distance in which 95% of the directed energy 33 is absorbed within luminescent thermally conductive element 32 in a transparent state. It should be noted that typically green bodies (e.g. unsintered parts) are pressed powders in which scattering dominates the transmission. As sintering and densification occurs, the pressed powders can transition to translucent and eventually transparent states approaching the optical and thermal properties of the material in single crystal form. In the case of eutectic ceramics such as, but not limited to, Al2O3/YAG, Al2O3/(Y,Gd)AG, Al2O3/GaG, and other eutectic mixtures of Al2O3, Yag, Spinel, Zirconia, and other oxides, material properties can exceed the performance of individual single crystal oxides regarding thermal stability and crack resistance. The use of eutectic ceramics contain doped oxides are a preferred embodiment of this invention. The formation of eutectic ceramics in which a least one of the phases is luminescent is also a preferred embodiment of this invention. The use of fiber lasers to form doped eutectic ceramics by rapid heating methods is a preferred embodiment of this invention. As an example, alumina and 2% cerium doped (Y,Gd)AG may be fused into an eutectic ceramic using a 200 W Yb fiber laser expanded into a 4 mm×4 mm flat top beam which irradiates a beaker filled with the constituent powders disclosed above. In a manner similar to skull processing, the powder that surrounds the irradiated area forms the crucible and the absorption depth of the materials allow for a spherical molten ball to form within the powder within a matter of seconds. Using this approach, very high heating and cooling rates can be efficiently realized. In the molten state addition processing such as forging may be done to create non-spherical shapes. In general, narrow band directed beams 33 within the intrinsic transmission window 34 can sinter and consolidate the luminescent thermally conductive element 32. In the case of sintering the powders consolidate based on diffusion driven growth as stated above. While sintering does allow for the formation of solid and even transparent solid materials (especially in the case where hot pressing is used) long heating cycles and high pressures are typically required. As a preferred embodiment of this invention melt fusing is a method of rapidly forming luminescent solid materials from both mixtures of non-luminescent/luminescent powders and from non-luminescent powders based on heating using an efficient fiber laser source. As an example of a melt fused solid, a luminescent solid may be formed using oxide powders within a container in which the laser input impinges on the powder not the container and forms a molten mass within the powder. More specifically, a mixture of yttrium oxide, aluminium oxide, gadolinium oxide and a rare earth dopant comprising at least one of the following elements Ce, Pr, Dy, Cr, or other element which luminesces within a garnet crystal lattice is melted using a fiber laser source to the point that a molten ball is formed within a powder compact. As an example, cerium ammonia nitrate may be dissolved in water mixed with yttrium oxide, gadolinium oxide, and aluminum oxide, dried to remove the water, placed in a beaker and then melt fused into a luminescent solid using a 1 KW Yb doped fiber laser. The powder compact forms a crucible for the molten ball thereby eliminating contamination from the containment vessel. The ability to rapidly heat and cool the molten ball allows for high crystallinity and high efficiency luminescence. Using this approach an additional high temperature firing step required to create Ce doped (Y,Gd)AG phosphor powders and a grinding step to create fine powders after the firing step is eliminated. A major issue for forming luminescent solids is uniformity of the dopant and various other oxides. In sintering operations this typically requires a spray drying or other mixing step and forming step (e.g. tape casting, roll compaction, hot pressing) which can not only lead to contamination but always creates some aggregation effects. These aggregation effects include settling and other non-uniformities which introduce composition variations. For luminescent materials in particular this leads to low yields especially when tight color temperature requirements are needed as in the case of solid state lighting. The use of melt fusing step inherently creates evenly distributed dopant concentrations due to the high diffusion rates possible in the liquid state. In addition the rapid heating and cooling rates possible with the fiber laser based melt fuse approach disclosed allows for higher quality crystallites than sintered based approaches. While both laser based sintering and melt fusing are disclosed as alternative means of forming luminescent solids, the inclusion of at least one melt fuse step in the processing of the luminescent solid is a preferred embodiment of the invention. The use of various atmospheres including, but not limited to, vacuum, inert, high pressure, and the introduction of various chemical vapors is also included. As example, the laser irradiation may be projected through a window substantially transparent to the laser irradiation into a chamber which is pressurized to over 10,000 psi. Under these conditions the melting/fusing process can be substantially different than what is possible at atmospheric conditions. In a similar manner, vacuum and/or inert conditions can be used to allow for processing of oxygen sensitive materials like nitrides. Alternatively, the use of laser melting/fusing may occur at various steps within a conventional sintering process. As an example, a green body may be formed using injection molding, shear compaction, tape casting, or dry pressing. The green body may be burned out to remove any binder and then cold isostatic pressed to reduce the porosity of the green body and then laser melted or fused. It should be noted that absorption cross-section of the laser is significantly different in a loose powder than in a compacted part. This embodiment includes the formation of luminescent powders based on laser melt fusing which would then be used in subsequent sintering or melt fusing processes. As an example, yttrium oxide, aluminum oxide, and cerium oxide powders may be melt fused into spherical powders for subsequent processing. Alternately, calcined or fully processed phosphor powders converted into spherical powders using fiber lasing fusing. The spherical nature that results from the laser fusing enhances flowability for subsequent consolidation processes such a dry pressing, injection molding, tape casting, or shear extrusion. The use of this process is intended to replace more conventional spray drying in which a binder is introduced into powders and then sprayed into a cyclonic chamber to form spherical particles with a uniform composition of the various powders that lend themselves to better compaction. By using the laser technique, spherical particles can be formed of uniform composition with the contamination issues associated with conventional spray drying techniques. In this case the powders may be melt fused by moving through the fiber laser beam or the fiber laser beam may be moved or scanned across the powders. Again both non-luminescent /luminescent mixtures and non-luminescent powders can be melt fused to create starting materials for subsequent consolidation into a solid as disclosed above. The use of drying steps either laser based or via other heating means to eliminate water and other volatile materials chemically or physically absorbed onto the surface of the powders prior to melt fusing is also a means of reducing porosity in the luminescent solid. It is noted that controlling porosity serves two purposes allowing for enhanced extraction due to optical scattering out of the high refractive index of the solid luminescent element but not too much porosity to reduce efficiency or degrade thermal conductivity. The described process of forming a luminescent thermally conductive material using laser melt fusing can be advantageous in densifying the luminescent ceramic material without requiring conventional sintering or high temperature isostatic pressing. It can also aid in controlling grain size to optimize the optical properties of the luminescent ceramic material. Grain size and density can each be independently controlled using laser melt fusing of the ceramic material.

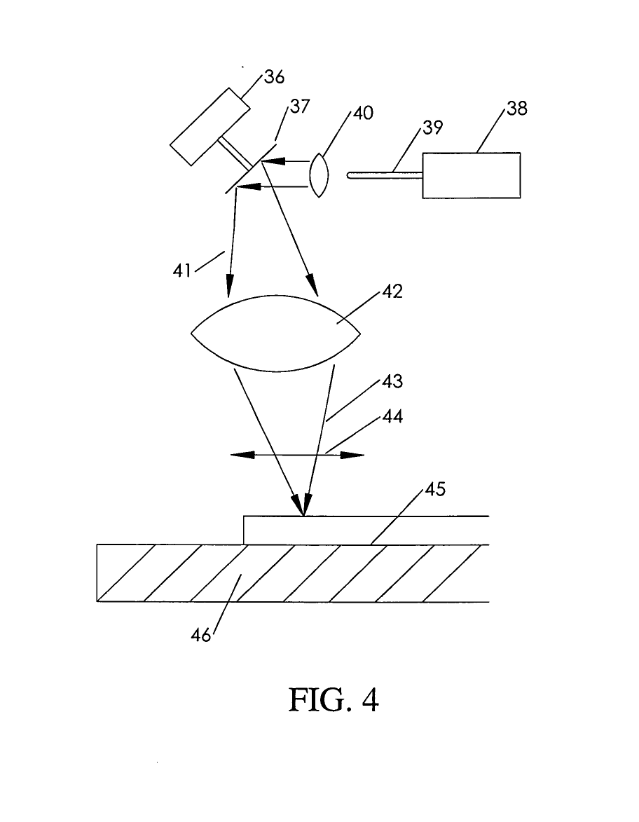

FIG. 4 depicts a fiber laser based galvanometer system for firing conductive silver traces with inorganic binders. As stated earlier, localized efficient directed heating of inorganic materials is critical for robust solid state lighting. In this embodiment, a fiber laser 38 is coupled through optical fiber 39 to imaging element 40 onto at least one mirror 37 moved by at least one galvo 36. The galvo moved mirror reimages light output 41 through lens 42 to become focused light output 43 onto conductive trace 45 on luminescent element 46. At least one galvo 36 moves at least one mirror 37 which translates focused output 43 in lateral direction 44. Local heating above the sintering temperature of the conductive 45 minimizes the heating of the underlying luminescent element 46. In this embodiment, organic and inorganic binders, composites, and luminescent materials can be used in luminescent element 46. such as polysilazane containing fluorescent dyes or phosphors.

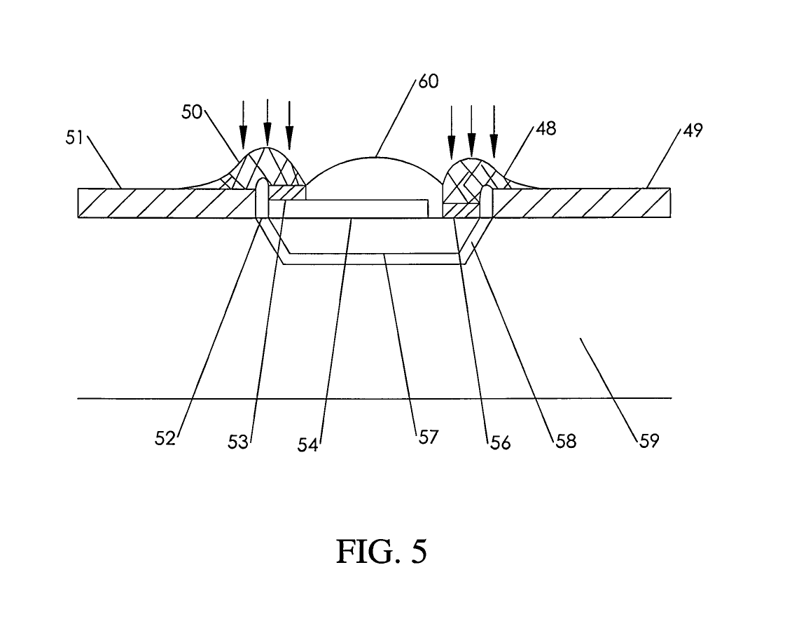

FIG. 5 depicts laser fused interconnects 48 and 50 for an embedded LED 57 within a thermally conductive luminescent element 59. As in earlier examples, an embedded LED 57 is bonded by substantially transparent bonding layer 58 into a recess within thermally conductive luminescent element 59. Dielectric barriers 60 and 52 are applied and then cured or fused over LED 47 such that the top and sides of LED 47 are electrically isolated from the subsequent conductive traces except where contact pads 53 and 56 are. On top of dielectric barriers 60 and 52, conductive interconnect 49 and 51 are printed and fused. Laser fused interconnects 48 and 50 may be separately printed and sintered using directed energy 47 thereby reducing the heat load on embedded LED 57. This reduced heat and separate printing is especially important for the p-side layer 54 which is difficult to maintain low resistance ohmic contact to. Fiber laser based systems are preferred sources of directed energy 47 due to high efficiency and the wavelength of operation. Using this approach the high cost of wirebonding can be eliminated.

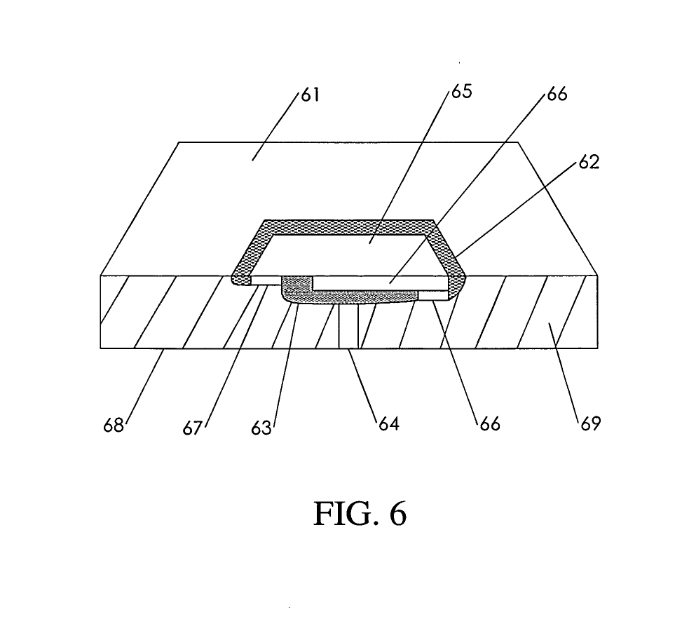

FIG. 6 depicts an embedded LED package with high temperature metal contact pads 69 and 68. The embedded LED 65 is bonded into thermally conductive luminescent element 61 using transparent high temperature bonding layer 62 consisting of, but not limited to, polysiloxanes, polysilazanes, low temperature glasses and low temperature oxides. An additional transparent dielectric isolation layer 63 electrically isolates the non-contact surfaces of the LED from the conductive high temperature metal contacts 69 and 68. As in all these embodiments, high reflectivity low absorption materials such as silver and silver filled inks and pastes are preferred for high temperature metal contacts 69 and 68 to reduce optical losses within the package. Optionally a dielectric barrier 64 may be added to minimize bridging in secondary solder process of the package to an underlying submount (not shown).

LED contact pads 66 and 67 are directly fused to the high temperature metal contact pads 69 and 68 during the sintering process. Direct energy will sinter and bond high temperature metal contact pads 69 and 68, dielectric barrier 64, transparent dielectric isolation layer 63 and transparent high temperature bonding layer 62. As an example, laser energy can be directed through the thermally conductive luminescent element 61 and onto transparent high temperature bonding layer 62 such that transparent high temperature bonding layer 62 is fused to embedded LED 65. The laser energy must be of a wavelength that transmits readily through the thermally conductive luminescent element but is strongly absorbed the transparent high temperature bonding layer 62. Wavelength specific dyes can be used within transparent high temperature bonding layer 62. In general, the direct energy wavelength and materials are selected such that localized heating occurs within the semiconductor layers of the LED.

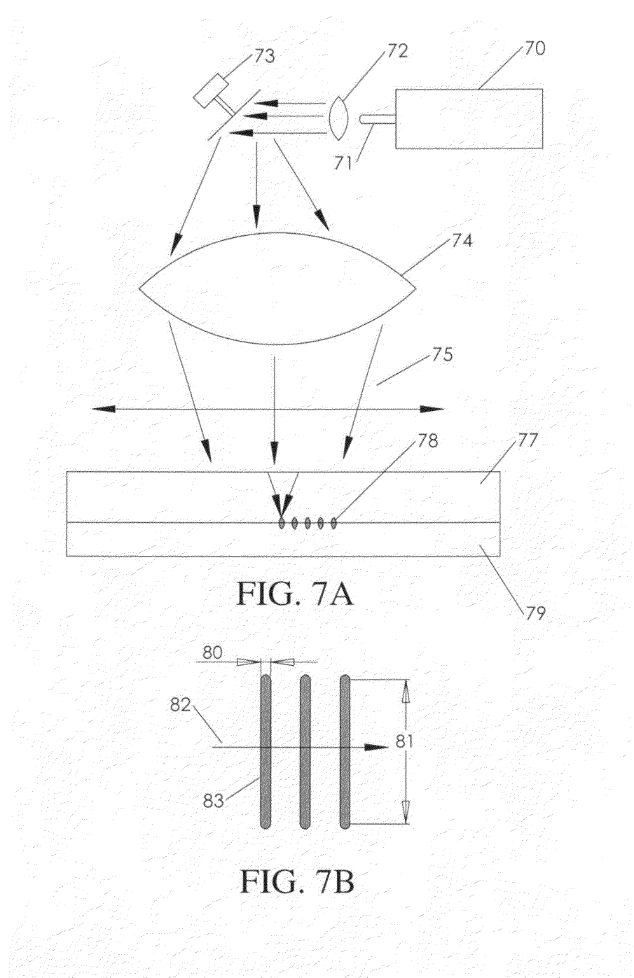

FIG. 7A depicts a fiber laser based liftoff process for harvesting thin nitride foils. In this embodiment, short wavelength fiber laser source 70 is coupled by optical fiber 71 through imaging optics 72 and mirror and galvo system 73 and then imaged through lens 57 such that the focused output 75 can be very rapidly linearly translated as shown in motion 76 across the wafer 77. Typically wafer 77 is a double side polished sapphire with a 10 to 100 micron thick nitride layer grown epitaxially on it. As shown in the close-up view of FIG. 7B, focused light output 75 is preferably a linear spot 83 where the width 80 to length 81 ratio is greater than 1 to 10 and the width 80 is less than thickness of nitride layer 79. The pulse rate and scanning speed 82 is coupled to produce a pattern of cuts at the interface between nitride layer 79 and the rest of the wafer 77. Using this technique, very large area of very thin freestanding nitride foils can be harvested from the wafer 77 without breakage. In addition extraction elements are formed which eliminate the need for future etching steps in the LED manufacturing process. Unlike xy tables, galvos can scan at much higher rates in both the x and y direction which allows for the use of higher repetition rate lasers which greatly increase the speed at which a given area can be removed. As an example, a quadrupled Yb doped fiber laser emitting in the UV with non-round core shape can create the linear spot 83. The use of linearly polarized fibers will further reduce the width 80 to length 81 ratio of the linear spot 83. As previously disclosed, the ability to form narrow linear spots 83 is critical to reducing cracking in nitride layer 79. Fiber laser due to their ability to have shaped cores allow for much more precise beam shaping than conventional diode-pumped solid-state (DPSS) lasers. This is due in part the higher beam quality of fiber lasers compared to DPSS lasers. In addition the cost of fiber lasers is significantly lower than conventional DPSS.

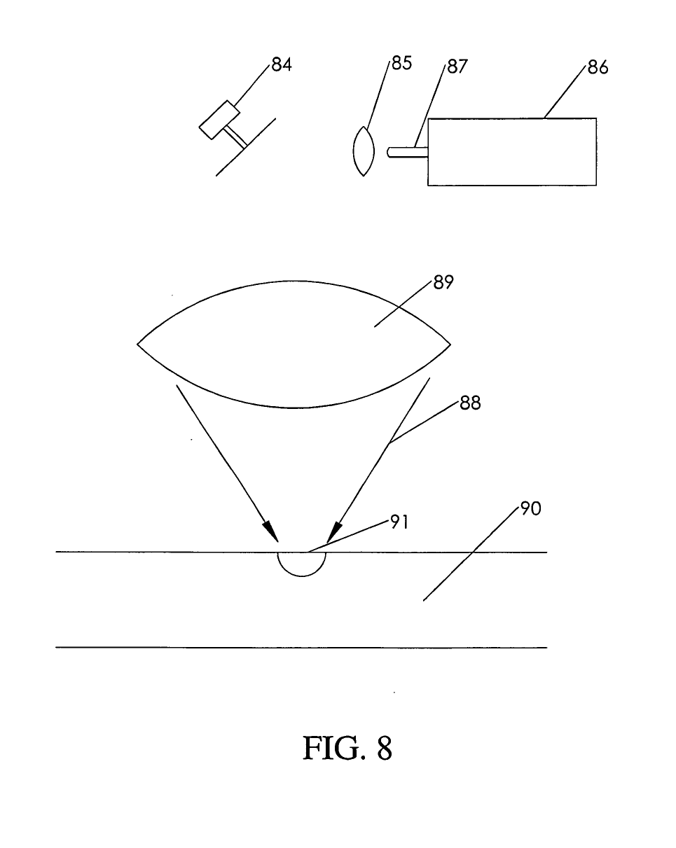

FIG. 8 depicts a fiber laser trimming system for trimming and cutting pockets in luminescent element 90. The fiber laser source 86 is coupled by optical fiber 87 through lens 85 onto at least one galvo system 84 and imaged via lens 89 such that output 88 can be used to cut the depression 91 forming the pocket. The higher speed of this approach dramatically reduces cutting time. This system trims the color temperature, color coordinates, intensity, spatial output pattern of the embedded LED packages shown in FIG. 6 after assembly by removing spatially luminescent material after assembly.

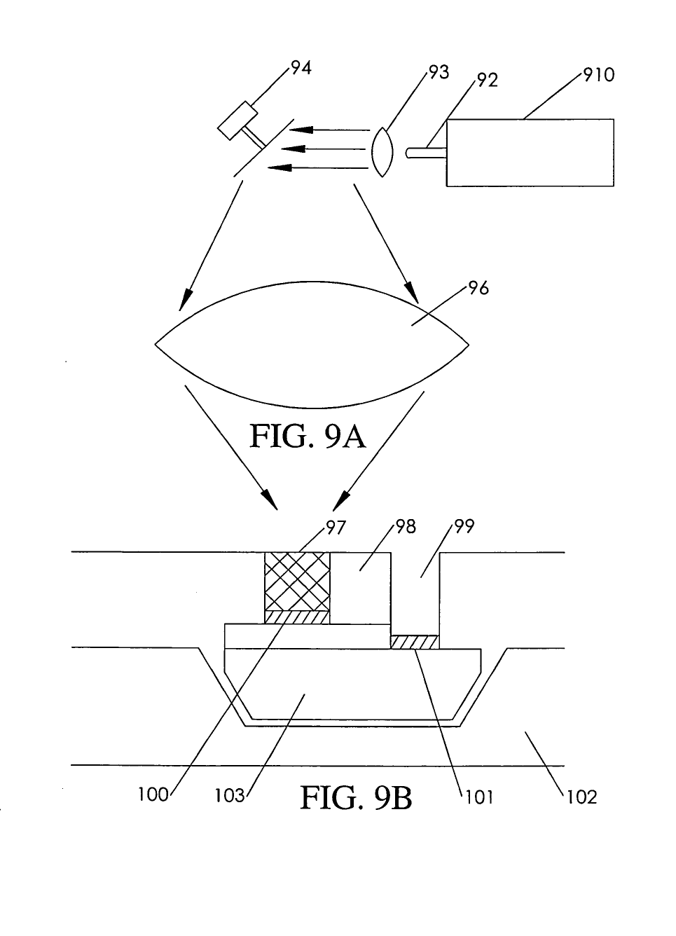

FIG. 9A depicts fiber laser based by cutting system for embedded LED. Fiber laser source 910 is coupled by optical fiber 92 through lens 93 onto at least one galvo system 94 such that output 95 is imaged through lens 96 onto dielectric layer 98. As shown in FIG. 9B, a pattern recognition system is capable of identifying the contact pads 100 and 101 such that galvo system 94 can direct the direct energy from output 95 into the volume 97 such that material is removed via ablation. Via 99 allows access to contact pad 101 on embedded LED 103 within thermal conductive wavelength element 102.

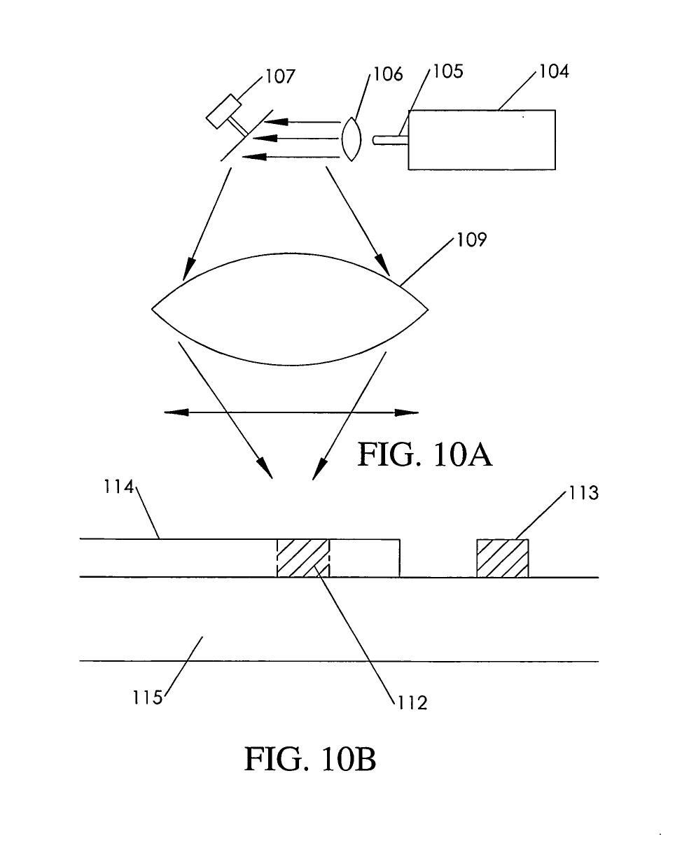

FIG. 10A depicts selective curing of transparent dielectric layers based on a galvo directed fiber laser. In this case, a longer wavelength fiber laser, such as 2 micron, is preferred due to better absorption of the longer wavelength light beam within the transparent dielectric layer 114. Fiber laser source 104 is coupled by optical fiber 105 through imaging lens 106 to at least one galvo system 107 to direct output 108 through lens 109 such that focused output 111 can be moved as in linear motion 110 across the piece. Energy is localized as shown in FIG. 10B within volume 112 by focusing and the high absorption of the longer wavelength fiber laser source. As an example, sintered transparent dielectric 113 is formed on thermally conductive luminescent element 115 after excess unsintered material is removed via rinsing, etching, or mechanical means. The combination of longer wavelength fiber laser output that is strongly absorbed in materials such as polysilazane, polysiloxane, and glasses enables the local sintering of high temperature materials temperature sensitive materials and devices.

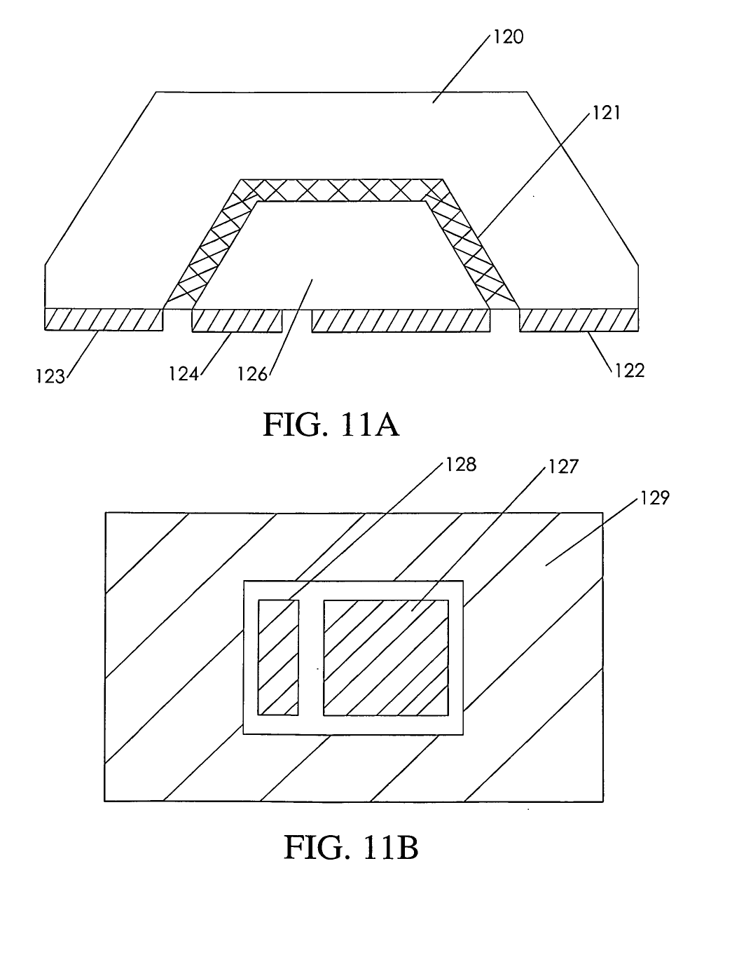

FIG. 11A depicts a direct attach LED 126 with contact pads 125 and 124 bonded into a melt fused solid luminescent element 120 with bonding layer 121 to form a substantially lambertian emitter. An advantage of the design is that multiple emitters can be placed against each other forming a continuous emitter source. Optionally reflector and bond pads 122 and 123 may be added to solid luminescent element 120 to enhance thermal extraction from the entire emitter and to direct light from the emitter. While reflector and bond pads 122 and 123 are shown on only one surface of solid luminescent element 120 having a truncated pyramid shape, it is anticipated that other shapes of solid luminescent element 120 and more or less coverage of its surface area by reflector and bondpads 122 and 123. In particular the formation of directive optic with reflective side walls such that the majority of the light generated by the direct attach LED 126 and solid luminescent element 120 is for directional light sources. Bonding layer 121 may consist of, but not limited to, polysiloxane, glasses, polysilazane, and other transparent or translucent high temperature materials. In particular the use of thermoplastic polysilazane resins with and without luminescent or fluorescent elements is also disclosed. The addition of luminescent elements in bonding layer 121 allows for color tuning and the use of environmentally sensitive luminescent materials such as sulfides. Reflector and bondpads 122 and 123 may consist of silver, gold, tin, or other metals. As shown in FIG. 11B, a corresponding solder pattern can be used to extract heat and/or electrically interconnect the direct attach LED 125 and solid luminescent element 120 to an underlying substrate not shown. Bonding region 127 would correspond to reflector and bonding pad 122 and 123, while bonding area 128 and 127 would corresponding to contact pads 124 and 125 respectively. While reflector and bondpad 122 and 123 are shown in this figure to be electrically isolated from contact pad 124 and 125 it is anticipated that electrical interconnect to direct attach LED 126 could be done through isolated traces on solid luminescent element 120 thereby allowing for larger spacing between bonding regions 128 and 127. In typical direct attach LED solder masking is required due to the small spacing between contact pads 124 and 125. As an example direct attach LED 126 could be embedded further into solid luminescent element 120 such that two electrically isolated reflector and bond pads 122 and 123 could extend over contact 124 and 125. An optional dielectric thermally conductive layer could also be added such that a larger bonding region with greater separation between 128 and 127 can be realized.

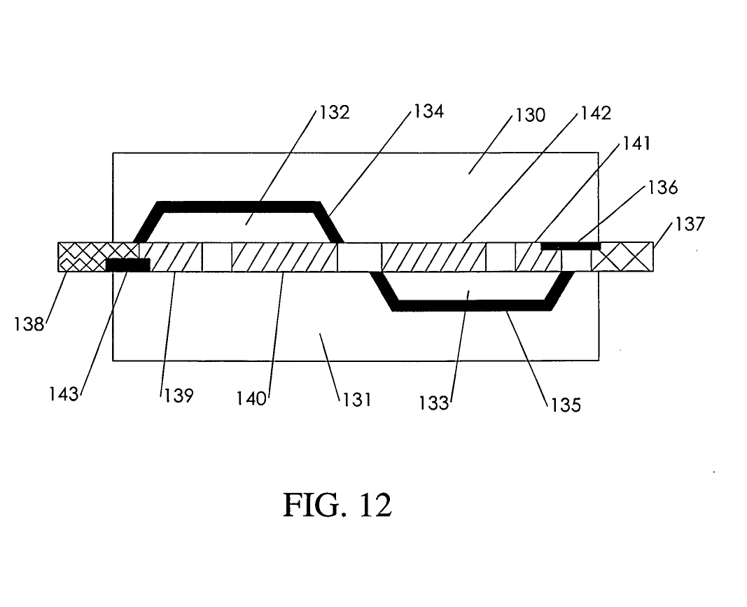

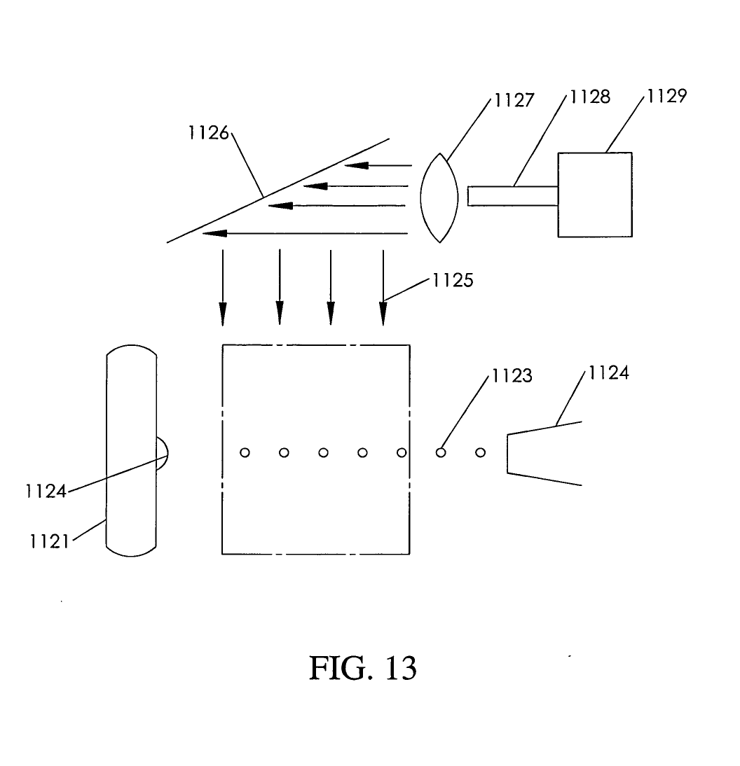

FIG. 12 depicts a substantially isotropic emitter containing at least two direct attach LED 132 and 133 embedded between at least two solid luminescent elements 130 and 131. In this configuration the at least two direct attach LED 132 and 133 face opposite directions and their corresponding electrical interconnect 136 and 143 and output contact/seals 138 and 137 are sandwiched between at least two solid luminescent elements 130 and 131. At least two direct attach LEDs 132 and 133 may be UV, visible, IR or combinations of the each wavelength range. The at least two solid luminescent elements 130 and 131 provide at least one of the following functions; converting at least a portion of the output from at least one of at least two direct attach LEDs 132 and 133 to another wavelength range; conducting heat away from at least two direct attach LEDs 132 and 133 into a large volume and eventually surface area such that cooling either based on conduction, convection, and/or radiation can be more effective realized; providing a support for the electrical interconnect 136 and 143; coupling light out of the at least two direct attach LEDs 132 and 133; mixing the various wavelengths emitted by the at least two direct attach LEDs 132 and 133 and the wavelengths emitted by the luminescent materials in the device; and creating a desired far field output intensity and spectral distribution. As an example, the at least two solid luminescent elements 130 and 131 may form a cylinder when put together with the at least two direct attach LEDs 132 and 133 mounted substantially near the center of the cylinder. This example would form a linear source with essentially isotropic emission radially. Spherical, square, triangular and other forms are also embodiments of this invention. In this case with the at least two direct attach LEDs, one LED 132 protrudes into solid luminescent element 130 while the other direct attach LED 133 protrudes into solid luminescent element 131. This configuration can be used to increase thermal and optical coupling between the at least two direct attach LEDs and the solid luminescent element that the at least two direct attach LEDs protrude into The shape of the pockets into which the LEDs 132 and 133 are embedded may be matching or non-matching to the shape of the at least two direct attach LEDs protruding into the pocket. In particular the pocket may be used to contain a specific amount of luminescent material to control the color of the output from the device. Bonding layers 134 and 135 may be transparent dielectric materials as previously disclosed. Bonding layers 134 and 135 may or may not contain luminescent materials for conversion of the at least a portion of the output from at least two direct attach LED 133 and 132 to another wavelength range. Preferred materials are silicones, polyimides, polysilazanes, epoxy, low temperature glasses and low temperature oxides. Phosphor powder and fluorescent dyes may be added to the bonding layers 134 and 135. As an example, solid luminescent element 131 may consist of polycrystalline alumina injection molded sintered and hot isostatically pressed to form a thermally conductive translucent element with pockets with or without luminescent materials into which LED 133 and 132 protrude. The bonding layer 134 and 135 are silicone coatings containing a luminescent material. The bonding layer 134 and 135 are applied to the thermally conductive translucent element to form at least two solid luminescent elements 130 and 131. Additional bonding layers are also disclosed. Alternately, bonding layers 134 and 135 may be a liquid or gas which may or may not be static and may or may not include luminescent materials A preferred embodiment is the use of the solid luminescent elements 130 and 131 and output contacts/seals to form a channel through which water or gases can flow through the bonding layers 134 and 135 space thereby directly cooling at least two direct attach LED 132 and 133 and at least solid luminescent elements 130 and 131 with the least thermal resistance between these heat source and cooling media which is the water or gases.

FIG. 13 depicts a thermal spray system based on a fiber laser heating zone. In conventional laser based thermal spray systems, either the particles or droplets 1123 are heated within the nozzle or spray gun 1124 and then transported via a gas to the deposition substrate 1121 or the laser impinges on deposition substrate 1121. In both cases, the particles or droplets 1123 surface temperature is not actively controlled between the nozzle or spray gun 1124 and the deposition substrate 1121. In the case where the heating occurs within the nozzle or spray gun 1124, particles or droplets 1123 are heated to very high temperatures and then cool as they travel between nozzle or spray gun 1124 to deposition substrate 1121. This cooling limits the distance between nozzle or spray gun 1124 and deposition substrate 1121 and limits the particle size of particles or droplets 1123 due to cooling effects. If the distance is too large, the particles or droplets 1123 will cool before they reach deposition substrate 1121. Alternately, if the particles or droplets 1123 are too small they lack the thermal mass to maintain their temperature before impinging on the deposition substrate 1121. In the case where the heating occurs at the deposition substrate 1121, only high temperature substrates can be used and again the particles or droplets 1123 temperature is not controlled between nozzle or spray gun 1124 and deposition substrate 1121. A fiber laser based heating zone approach allows for careful control of the temperature of the particles or droplets 1123 between the nozzle or spray gun 1124 and the deposition substrate 1121. Fiber laser based systems are capable of generating very high output powers with efficiencies approaching 50%.

In addition, high beam quality allow for the creation of very uniform intensity profiles over very large areas. As an example, a 2 Kilowatt Yb fiber laser 1129 with a square fiber output 1128 can be imaged using lens 1127 and optic 1126 to create 4 mm×4 mm beam 1125 that is substantially parallel to the surface of deposition substrate 1121. In this case, alumina/Ce-doped (Y,Gd)AG powders 1123 are sprayed out of nozzle or spray gun 1124 via a high pressure air through heating zone 1120. The temperature of particles or droplets 1123 will be determined by the power density, particle size, absorption coefficients of particles or droplets 1123 to the emission wavelength of fiber laser 1129, and the length of heating zone 1120. Multiple heating zones and/or variable intensity profiles within heating zone 1120 allow controlled heating profiles of the particles or droplets 1123 to be realized as they transition between nozzle or spray gun 1124 and deposition substrate 1121.

The thermal time constant of the particle or droplets 1123 is directly proportional to the volume, heat capacity, and density of the particle. The thermal time constant of the particle or droplets 1123 is inversely proportional to the convective heat transfer coefficient and surface area of the particle. By controlling the heating zone 1120 length and power density, a wide range of the heating profiles can be realized. Droplets of solutions can also be processed using this technique.

Typical spray velocities are between 100 m/sec and 1000 m/sec, as such exposure times within the heating zone 1120 can range from microseconds to milliseconds depending on the length of the heating zone and particle velocities. The high power density possible from the fiber laser 1129 allows for very high temperatures to be realized on particles or droplets 1123. This can be used to affect the composition and structure of deposition 1122. In many cases rapid thermal processes can be used to minimize decomposition and allow for the creation a wide range of compositions and crystal structures. The use of this apparatus to form luminescent wavelength conversion elements is a preferred embodiment of this invention. Optionally the deposition substrate 1121 and deposition 1122 may be heated either via an external heating source or by moving them into the heating zone 1120.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention as defined in the following claims.

1. A solid state light source comprising:
at least one solid thermally conductive luminescent element;
at least one LED embedded within the at least one solid thermally conductive luminescent element; and
an electrical interconnect structure for making electrical connection to the at least one LED;
wherein the solid state light source is fabricated in accordance with a process in which at least one step of the process includes irradiating a selected component of the light source with a laser beam, to achieve a selected processing goal rapidly and without unwanted heating of the component.

2. The solid state light source of claim 1, wherein the laser beam is provided by a fiber laser.

3. The solid state light source of claim 1, wherein:
the selected component of the light source irradiated by the laser beam is the at least one solid thermally conductive luminescent element; and
the selected processing goal achieved by laser irradiation is selected from the group consisting of forming the solid thermally conductive luminescent element, cutting one or more pockets in the solid thermally conductive luminescent element, and dicing the solid thermally conductive luminescent element into sub-elements.

4. The solid state light source of claim 3, wherein the laser beam is provided by a fiber laser.

5. The solid state light source of claim 1, wherein:
the selected component of the light source irradiated by the laser beam is the at least one solid thermally conductive luminescent element; and
the selected processing goal achieved by laser irradiation is sintering or melt fusing transparent/translucent ceramic wavelength conversion elements in the solid thermally conductive luminescent element or a spherical powder.

6. The solid state light source of claim 5, wherein the laser beam is provided by a fiber laser.

7. The solid state light source of claim 1, wherein:
the selected component of the light source irradiated by the laser beam is the at least one solid thermally conductive luminescent element; and
the selected processing goal achieved by laser irradiation is trimming light source to adjust the color temperature of packages and self cooling light sources, by spatially ablating the transparent/translucent ceramic wavelength conversion elements that are part of the solid thermally conductive luminescent element.

8. The solid state light source of claim 7, wherein the laser beam is provided by a fiber laser.

9. A method of forming a solid state light source, comprising:
forming at least one solid thermally conductive luminescent element;
forming and embedding at least one LED within the at least one solid thermally conductive luminescent element; and
forming an electrical interconnect structure for making electrical connection to the at least one LED;
wherein the at least one forming step includes irradiating a selected component of the light source with a laser beam, to achieve a selected processing goal rapidly and without unwanted heating of the component.

10. The method of claim 9, wherein the laser beam is provided by a fiber laser.

11. The method of claim 9, wherein:
the selected component of the light source irradiated by the laser beam is the at least one solid thermally conductive luminescent element; and
the selected processing goal achieved by laser irradiation is selected from the group consisting of forming the solid thermally conductive luminescent element, cutting one or more pockets in the solid thermally conductive luminescent element, and dicing the solid thermally conductive luminescent element into sub-elements.

12. The method of claim 11, wherein the laser beam is provided by a fiber laser.
